(19) United States
(12) Patent Application Publication
(10) Pub. No.: US 2023/0400515 A1
(43) Pub. Date: Dec. 14, 2023

(54) DETERMINATION AND CLASSIFICATION OF ELECTRIC MOTOR WINDING INSULATION DEGRADATION

(71) Applicant: MAGNA INTERNATIONAL INC., Aurora (CA)

(72) Inventors: Ashutosh PATEL, Montreal (CA); Chunyan LAI, Montreal (CA); Narayan Chandra KAR, Tecumseh (CA); Gerd SCHLAGER, Kefermarkt (AT); Martin WINTER, Dietach (AT); Alexander EXL, Sankt Valentin (AT); Lakshmi Varaha IYER, Windsor (CA)

(21) Appl. No.: 18/035,336

(22) PCT Filed: Nov. 8, 2021
(86) PCT No.: PCT/CA2021/051588

§ 371 Date: May 4, 2023

Related U.S. Application Data
(60) Provisional application No. 63/111,366, filed on Nov. 9, 2020.

(51) Int. Cl. G01R 31/34

(52) U.S. Cl. CPC G01R 31/346; G01R 31/343

(57) ABSTRACT

A method and system for characterizing a state of health of a winding of an electric machine are provided. The winding may include one or more stator windings in an electric machine, for example, a permanent magnet synchronous machine (PMSM). The method comprises: applying a voltage pulse to the winding; measuring a phase current signal of a current supplied to the winding; determining a high-frequency transient current based on the phase current signal. The state of health of the winding may be calculated as a function of change in frequency spectrum of the high-frequency transient current. The method may include calculating a plurality of packets using a wavelet packet decomposition of the high-frequency transient current; and determining one or both of: the state of health or a classification of degradation, using an indicator based upon at least one packet of the plurality of packets.

### CROSS REFERENCE TO RELATED APPLICATIONS

This PCT International Patent Application claims the benefit of and priority to U.S. Provisional Patent Application Ser. No. 63/111,366, filed Nov. 9, 2020, titled “Determination and Classification of Electric Motor Winding Insulation Degradation,” the entire disclosure of which is hereby incorporated by reference.

### FIELD

The present disclosure relates generally to detecting and characterizing insulation degradation in windings of electric machines.

### BACKGROUND

Variable speed drives are widely used in industry and in electric vehicles. These drives commonly employ fast switching power electronics devices with pulse width modulation (PWM). Drives with fast switching devices show great advantages at certain aspects. However, they can subject the insulation of machine windings to very high electrical stress, which can provoke pre-mature insulation failure in stator windings.

According to some accounts, about 70% of faults in the stator of electric machines are due to insulation failure, and Partial Discharge (PD) phenomenon is considered one of the main reasons for premature insulation failure. Insulation material used on stator windings is commonly constructed to be PD resistant. However, degradation in insulation may still result due to material decomposition, thermal stress, mechanical forces, and contamination from surrounding environments. Determining the health of insulation in an early stage can prevent major failure in machines and improve safety of equipment that uses electric machines.

Monitoring techniques can be characterized as either online or offline type. In offline monitoring, an electric machine is taken out of the service to perform tests. In online monitoring, the electric machine is kept in service while tests are performed. Online monitoring may provide advantages over offline monitoring in reduced downtime and improved availability of the electric machine.

### SUMMARY

In accordance with an aspect of the disclosure, a method for characterizing a state of health of a winding of an electric machine is provided. The method comprises: applying a voltage pulse to the winding; measuring a phase current signal corresponding to the voltage pulse; determining a high-frequency transient current based on the phase current signal; determining a frequency spectrum of the high-frequency transient current; and determining the state of health of the winding as a function of a change in the frequency spectrum of the high-frequency transient current

In accordance with an aspect of the disclosure, a method for characterizing a state of health of a winding of an electric machine is provided. The method comprises: applying a voltage pulse to the winding; measuring a phase current signal corresponding to the voltage pulse; determining a high-frequency transient current based on the phase current signal; calculating a plurality of packets using a wavelet packet decomposition of the high-frequency transient current; and determining at least one of: the state of health or a classification of insulation degradation based upon at least one packet of the plurality of packets.

### BRIEF DESCRIPTION OF THE DRAWINGS

Further details, features and advantages of designs of the invention result from the following description of embodiment examples in reference to the associated drawings.

FIG. 1 shows a block diagram of system in accordance with an aspect of the present disclosure;

FIG. 2 is a graph showing transient phase current curves for various degradation in accordance with the present disclosure;

FIG. 3 is a flow chart of steps in a method for current processing in accordance with the present disclosure;

FIG. 4 is a graph showing frequency spectrums for different degradation cases in accordance with aspects of the present disclosure;

FIG. 5 is a graph showing Mean Square Error (MSE) values representing State of Health (SOH) for various winding-ground and winding-winding cases;

FIG. 6 is a graph showing norms of packet p0 of a Wavelet Packet Decomposition (WPD) for various winding-ground and winding-winding degradation cases;

FIG. 7 is a graph average norms of packets p10 and p11 of a Wavelet Packet Decomposition (WPD) for various winding-ground and winding-winding degradation cases;

FIG. 8 is a flow chart listing steps in a first method for determining and characterizing state of health of winding insulation in an electric machine in accordance with aspects of the present disclosure; and

FIG. 9 is a flow chart listing steps in a second method for determining and characterizing state of health of winding insulation in an electric machine in accordance with aspects of the present disclosure.

### DETAILED DESCRIPTION

Referring to the Figures, wherein like numerals indicate corresponding parts throughout the several views, a system and method for characterizing state of health of winding insulation in an electric machine is disclosed.

There are various online monitoring techniques were proposed over the years like partial discharge monitoring, on-line surge test, leakage current monitoring, current sequence detection and transient current response-based monitoring. In this method, the transient current due to PWM excitation is obtained with current sensors available in a motor drive system. Then the current is processed to obtain state of health (SOH) of insulation. Here, the method capable of providing SOH of insulation and the type of degradation using wavelet packet decomposition (WPD) is proposed.

It is an objective of the system and method of the present disclosure to provide modeling and online monitoring of the State of Health (SOH) insulation of stator windings.

Some existing methods are known for online detection of the overall health of insulation within an electric machine. However, such existing methods are not generally capable of identifying the location or type of degradation. Generally, in any machine stator, there are two types of insulation. One is the ground wall insulation and the other is the insulation layer over wires. The methods proposed in some existing methods cannot differentiate types of insulation degradation. Moreover, existing methods are not able to detect a small variation in the insulation state of health.

In some methods, ground wall insulation may be monitored. Common mode voltage and current may be measured to determine state of health of insulation. Leakage current may be measured to determine insulation health state. However, these methods cannot distinguish between different types of degradation.

In some methods, an indicator is used to detect the overall health of stator insulation in induction machines. Transient current is measured and processed to determine the health of the stator's insulation. To summarize, some known methods are unable to classify types of degradation, and some known methods use indicators that cannot detect small variations in insulation state of health.

It is an aspect of the present disclosure to provide a methodology that is more accurate in providing the state of health (SOH) of stator insulation and which classifies the types of insulation degradation. A method of the present disclosure can provide SOH of ground wall insulation and wire insulation separately. The methodology of the present disclosure may use the current sensors in the motor drive system directly, so it does not require any additional sensors.

It is an aspect of the present disclosure to provide a method in which the current from current sensors at different phases will be measured when pulse-width modulation (PWM) excitation is applied. The current will be processed, and indicator will be calculated from wavelet packet transform which will provide the state of health of stator winding's insulation and type of degradation in the stator insulation. The indicators selected are norm and standard deviation of packets from wavelet packet decomposition of current signals. By observing the change in indicators, the SOH can be determined, and the type of degradation can be classified.

More specifically, it is an aspect of this disclosure to provide a method for online monitoring of the state of health and classification of a type of degradation of windings within an electric machine. The term “Online” may refer to an electric machine that is in situ, or which is connected to electrical and/or mechanical hardware of its operating environment. For example, the method and system of the present disclosure may be used to diagnose faults in an electric machine that is installed within an electric vehicle (EV). In some cases, the method may be performed as part of a periodic maintenance or system check. For example, an electric vehicle may perform the method of the present disclosure as part of a startup check to begin a driving session. In some embodiments, the method may be performed using hardware components, such as a motor drive and controller, that are already in place for operating the electric machine.

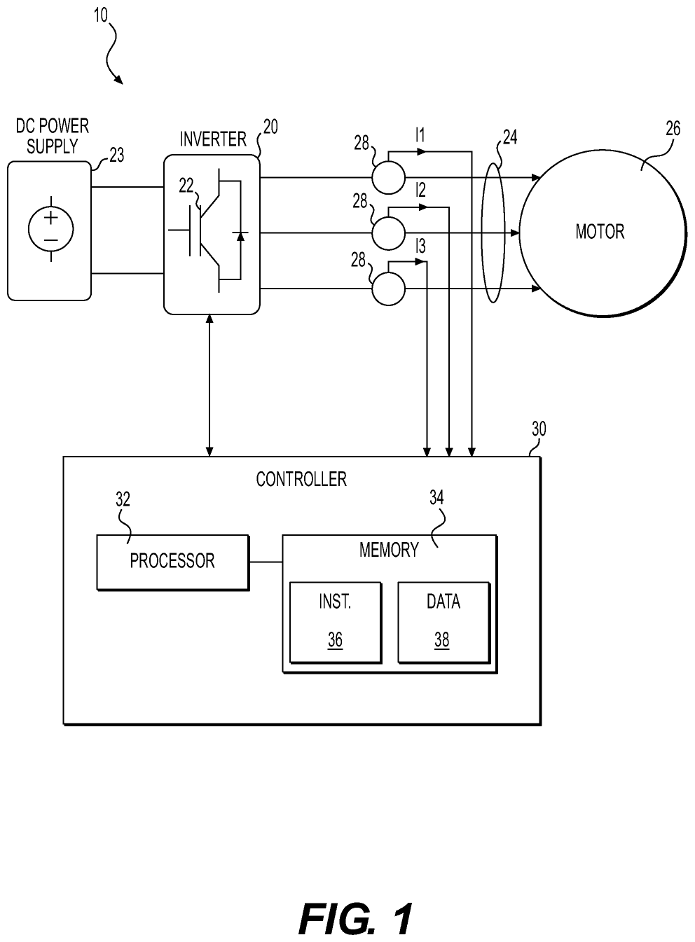

FIG. 1 shows a block diagram of system 10 in accordance with an aspect of the present disclosure. The system 10 includes an inverter 20 having one or more switching devices 22, such as field effect transistors (FETs) configured to switch current from a DC power supply 23 and to generate an AC power upon a set of motor leads 24. The motor leads 24 transmit electrical power between the inverter 20 and an electric machine 26. The electric machine 26 may be a permanent magnet synchronous machine (PMSM). However, the system 10 may be used with other types of electric machines such as wound field machines, induction machines, and/or reluctance machines. The electric machine 26 is shown as a 3-phase machine, however, the electric machine may have any number of phases. For example, the electric machine 26 may be a single-phase machine, a 3-phase machine, or a higher-order multiphase machine. The electric machine 26 may be used as a motor, a generator, or as a motor/generator that functions as both a motor and a generator. Current sensors 28 measure currents in corresponding ones of the motor leads 24. The system 10 may include other sensors, such as voltage sensors configured to measure voltages upon or between the motor leads 24.

The system 10 of FIG. 1 also includes a controller 30 in communication with the current sensors 28 to measure the currents in the motor leads 24. The controller 30 may also be in functional communication with the inverter 20 to control the operation of the motor drive 30 and/or to monitor parameters measured by sensors associated with the inverter 20. The controller 30 includes a processor 32 coupled to a storage memory 34. The storage memory 34 stores instructions, such as program code for execution by the processor 32. The storage memory 34 also includes data storage 38 for holding data to be used by the processor 32. The data storage 38 may record, for example, values of the parameters measured by the current sensors 28 and/or the outcome of functions calculated by the processor 32.

According to an aspect of the disclosure, current at different phases will be measured when PWM voltage excitation is applied to the motor leads 24. As shown in FIG. 1, phase currents I1, I2 and I3 can be measured from current sensors 28. The current will be processed, using a wavelet packet transform to produce an indicator, which can provide indications regarding state of health of stator winding insulation and a type of degradation in the stator of the electric machine.

The obtained currents, as measured by the current sensors 28, can be considered as a superposition of transient current and linear current rise and can be represented by following equation. The current i(t) rises at steady rate due to the machine's inductance L_{M}, and iₜᵣₐₙₛ is a high-frequency transient current which provides information related to high frequency behavior of machine. The current i(t) can be given by following equation (1):

$$i ( t ) = {i}_{trans} ( t ) + \frac{1}{{L}_{M}} {\int }_{- ∞}^{t} {V}_{PWM} ( t ) dt \qquad ( 1 )$$

Changes in the insulation state will lead to change in the machine's impedance at high frequencies and hence transient response of the current changes.

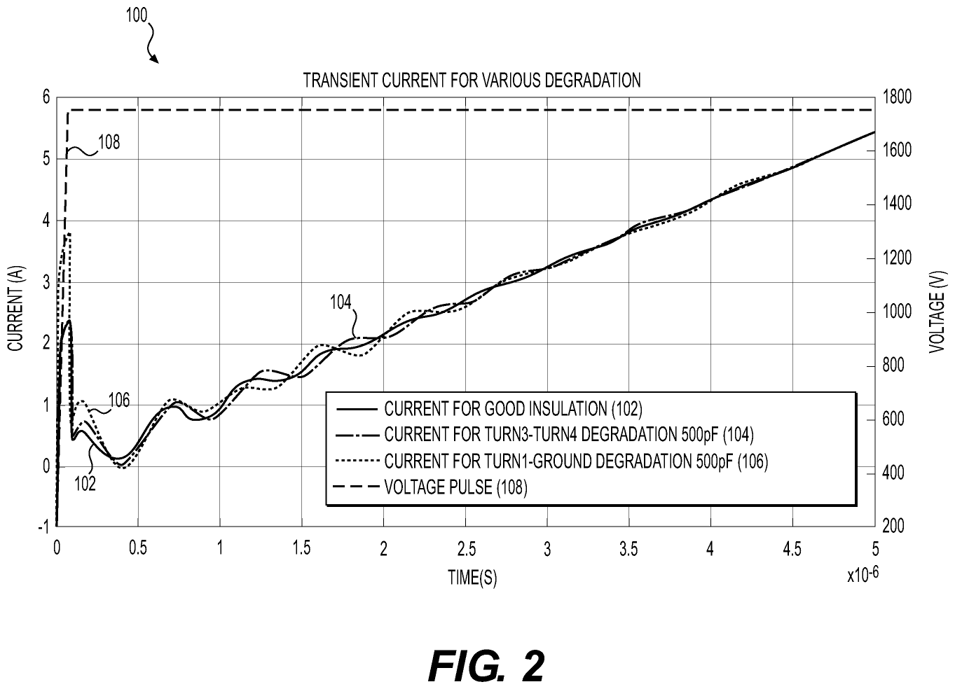

FIG. 2 is a graph 100 showing transient phase current curves for various degradation when a voltage pulse is applied. Graph 100 includes a first plot 102 showing current over time for a winding having little to no degradation (i.e. a “good insulation”). Graph 100 also includes a second plot 104 showing current over time for a winding that has a turn-turn degradation of 500 pF between turn 3 and turn 4. Graph 100 also includes a third plot 106 showing current over time for a winding that has a turn-ground degradation of 500 pF between turn 1 and ground. Graph 100 also includes a fourth plot 108 showing the voltage as a function of time.

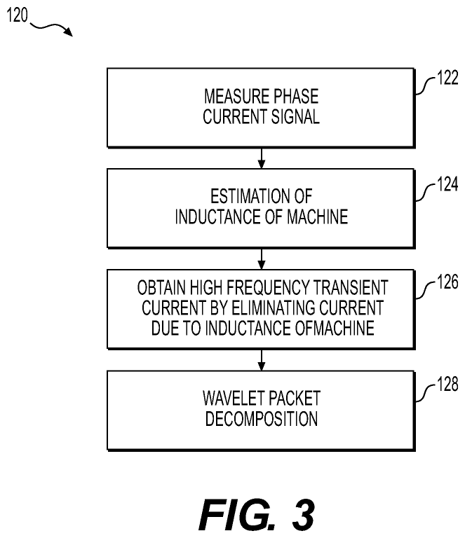

FIG. 3 is a flow chart of steps in a method 120 for current processing in accordance with the present disclosure. The method 120 includes measuring a phase current signal i(t) at step 122. The phase current signal i(t) may be measured by one of the current sensors 28 in response to application of a voltage pulse to the associated one of the motor leads 24. The voltage pulse may take the form of a pulse-width-modulated (PWM) voltage providing power to the electric machine 26.

The method 120 also includes estimating an inductance of the electric machine 26 at step 124. Step 124 may be performed by the processor 32 using information regarding the phase current signal i(t) measured in step 122. The inductance of the electric machine 26 may be an inductance of a given one of the windings in the electric machine 26. Alternatively, the inductance of the electric machine may be an average or a total inductance of two or more windings in the electric machine 26. The inductance of the electric machine 26 may include inductance of ancillary devices, such as wiring that is connected to the windings of the electric machine 26. In some embodiments, a rate at which the current rises due to the inductance of the winding may be estimated by applying polynomial curve fitting on the phase current signal i(t). The inductance may be calculated or estimated based on the estimated rate at which the current rises. Alternatively, the estimated rate at which the current rises due to the inductance may be used directly, without performing the intermediate step of estimating the inductance.

The method 120 also includes obtaining a high-frequency transient current iₜᵣₐₙₛ at step 126 by eliminating current due to inductance of the electric machine 26. The current due to inductance may be calculated or otherwise estimated and subtracted from the phase current signal i(t) measured in step 122 in order to obtain the high-frequency transient current iₜᵣₐₙₛ Some or all of step 126 may be performed by the processor 32 using the inductance of the electric machine determined at step 124. Alternatively, the high-frequency transient current iₜᵣₐₙₛ may be obtained directly from the transient current signal. For example, the high-frequency transient current iₜᵣₐₙₛ. may be obtained using a high-pass filter to block lower-frequency components of the phase current signal i(t).

Since the high-frequency transient current iₜᵣₐₙₛ provides information related to high frequency behavior of the electric machine, the the high-frequency transient current iₜᵣₐₙₛ may be further processed to determine SOH and type of degradation.

The method 120 also includes performing a Wavelet Packet Decomposition (WPD) step 128. Step 128 may also be performed by the processor 32 using the high-frequency transient current iₜᵣₐₙₛ obtained in step 128. The WPD may be used to determine state of health (SOH) and/or a type of degradation, such as turn-to-turn (TT) degradation or turn-to-ground (TG) degradation.

### Wavelet Packet Decomposition (WPD) and Indicators

The wavelet packet decomposition method is a generalization of wavelet decomposition that offers a richer signal analysis. Information from packets from WPD can be used as indicators to determine insulation state. By observing change in one or more indicators, SOH can be determined, and the type of degradation can be classified.

Finite Element based method is used to emulate various types of insulation degradation, and the current responses were obtained. Turn to Turn (TT) degradation, in which enamel between the strands of different turns is degraded, is emulated. The other type of degradation is Turn to Ground (TG) degradation, in which ground wall insulation is degraded.

The transient current iₜᵣₐₙₛ was processed using five level WPD. Five levels of WPD provides 32 packets, from p0 to p31. The number of levels of decomposition can be changed depending on requirements of a given test, such as the type of information to be obtained. Useful features can be extracted from these packets.

### SOH Determination Techniques

To determine SOH and type of degradation, the results from a healthy machine is used as reference. Then during the lifetime of the machine, results for that condition can be compared with the reference case to determine SOH and type of degradation. Here, two methods are proposed for overall SOH determination. One method uses change in frequency spectrum due to degradation. Various different indicators may be used to determine degradation based on the change in the frequency spectrum. In some embodiments, mean square error (MSE) is used as an indicator. For example, an indicator may be calculated based on an MSE of a difference between a measured frequency spectrum and a reference spectrum corresponding to a healthy machine. Other mathematical indicators can be used to quantify changes or deviations in the frequency spectrum. For example, a mean absolute error function or a mean squared deviation function may be used as an indicator to quantify changes or deviations in the frequency spectrum. The other method is based on WPD.

### SOH Determination 1: Frequency Spectrum-Based Method

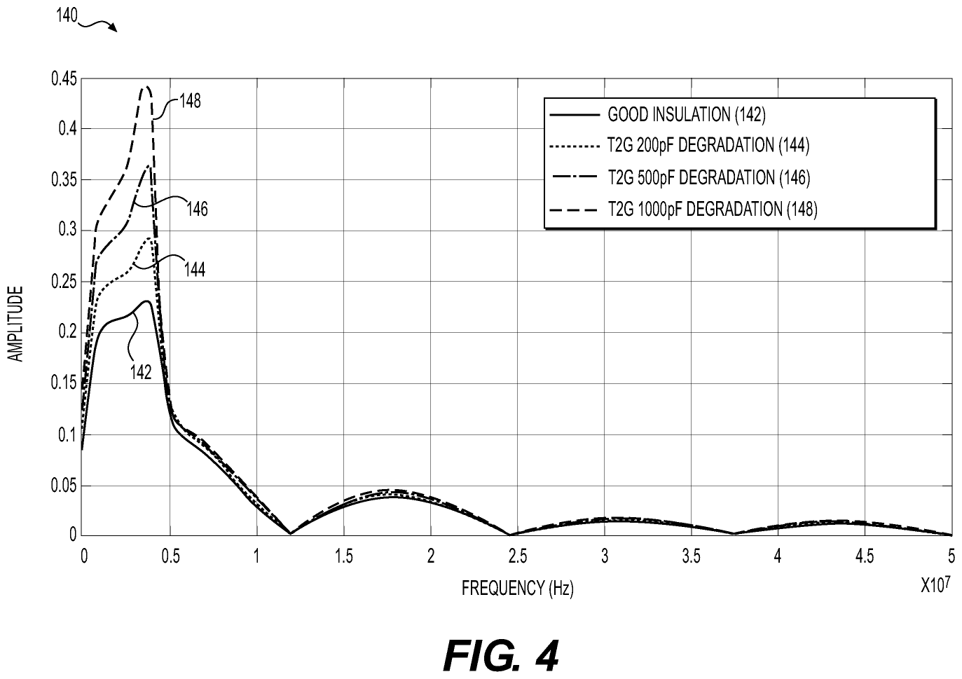

FIG. 4 is a graph 140 showing frequency spectrums for turn-2 to ground (T2G) type insulation degradation for different degradation cases. Graph 140 includes a first plot 142 showing a frequency spectrum where the turn-2 to ground insulation is in good condition. Graph 140 includes a second plot 144 showing a frequency spectrum of the turn-2 to ground insulation with a 200 pF degradation. Graph 140 includes a third plot 146 showing a frequency spectrum of the turn-2 to ground insulation with a 500 pF degradation. Graph 140 includes a fourth plot 148 showing a frequency spectrum of the turn-2 to ground insulation with a 1000 pF degradation.

FIG. 4 shows how frequency spectrum of the high-frequency transient current iₜᵣₐₙₛ changes for different levels and types of degradation. Change in the frequency spectrum is used to determine the SOH. Mean square error (MSE) of the spectrum with respect to a reference spectrum is used as indicator and can be given by following equation (2):

$${SOH}_{MSE} = \frac{1}{n} {\sum }_{i = 1}^{n} {( {Y}_{i}^{ref} - {Y}_{i}^{test} )}^{2} \qquad ( 2 )$$

where Yᵢ^{ref} is the amplitude of reference spectrum at the i^{th} frequency point and Yᵢ^{test} is the corresponding i^{th} frequency point amplitude in the spectrum obtained from the real-time test signal, from the winding with some amount of degradation.

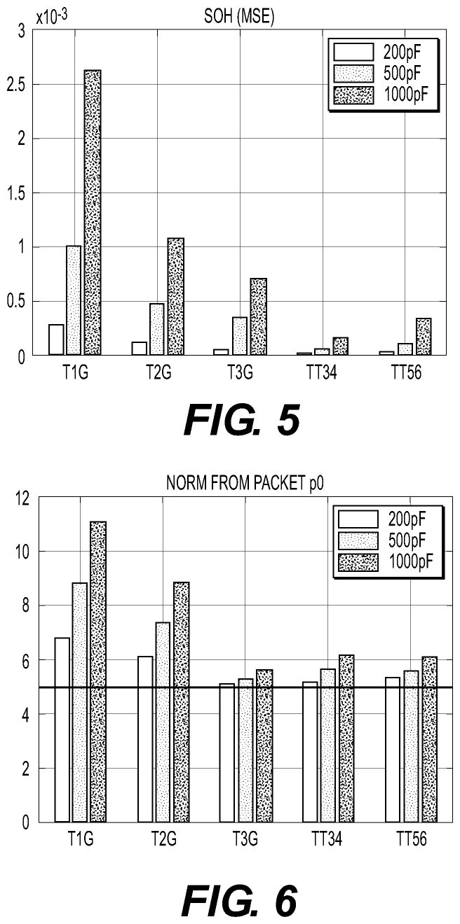

FIG. 5 is a graph showing Mean Square Error (MSE) values representing State of Health (SOH) for various winding-ground and winding-winding degradation cases. The degradation cases include turn-1 to ground (T1G), turn-2 to ground (T2G), turn-3 to ground (T3G), turn-turn degradation between turn 3 and turn 4 (TT34), and turn-turn degradation between turn 5 and turn 6 (TT56). Table 1, below, shows data corresponding to the graph of FIG. 5. For each type of degradation, there is a monolithic increase in the Mean-Square Error State of Health (SOH_{MSE}) values with higher level of degradation.

TABLE 1
SOH_{MSE}
SOH_{MSE}

| | 200 pF | 500 pF | 1000 pF |
|---|---|---|---|
| T1G | 0.0002852721 | 0.0010138 | 0.0026163 |
| T2G | 0.0001162084 | 0.0004744 | 0.0010739 |
| T3G | 0.0000541696 | 0.0003474 | 0.0007092 |
| TT34 | 0.0000085264 | 0.0000549 | 0.0001644 |
| TT56 | 0.0000279841 | 0.0001109 | 0.0003411 |

### SOH Determination 2: WPD Based

From results of WPD and frequency response analysis, it was demonstrated that norm of packet p0 can be used to determine overall SOH of the stator windings in the electric machine 26. Moreover, a new indicator can be established from results of WPD. The value of this new indicator may change according to degradation level (i.e. severity of degradation).

FIG. 6 is a graph showing norms of a first packet p0 of a Wavelet Packet Decomposition (WPD) for various winding-ground and winding-winding degradation cases. The degradation cases include turn-1 to ground (T1G), turn-2 to ground (T2G), turn-3 to ground (T3G), turn-turn degradation between turn 3 and turn 4 (TT34), and turn-turn degradation between turn 5 and turn 6 (TT56). Table 2, below shows data corresponding to the graph of FIG. 6.

TABLE 2
Norm from packet p0
Norm from packet p0

| | 200 pF | 500 pF | 1000 pF |
|---|---|---|---|
| T1G | 6.7996 | 8.8148 | 11.076 |
| T2G | 6.1084 | 7.3978 | 8.8527 |
| T3G | 5.0835 | 5.2648 | 5.6281 |
| TT34 | 5.2186 | 5.6773 | 6.1647 |
| TT56 | 5.3496 | 5.5965 | 6.1129 |

### Degradation Classification: WPD Based

By analyzing the results of WPD and frequency response analysis, it became clear that the norm of packet p10 and p11 can be used to determine type of degradation. The average value of the norms of packets p10 and p11 may be used as the indicator. Degradation in ground wall insulation results in an increase in the value of the indicator. While for turn-to-turn degradation, the value of the indicator remains the same. Based on the value of the indicator, the type of degradation can be determined.

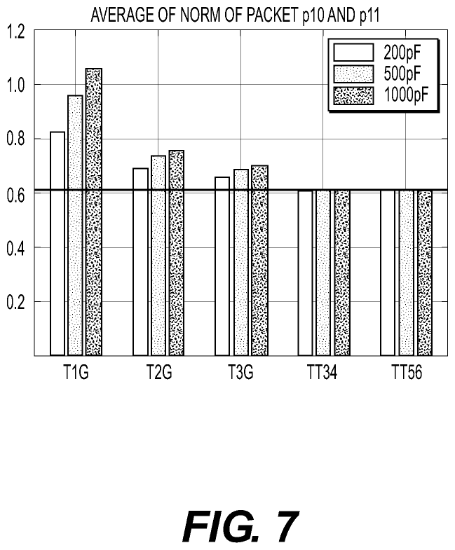

FIG. 7 is a graph of averages of the norm of an 11^{th} packet p10, and the norm of a 12^{th} packet p11 of a Wavelet Packet Decomposition (WPD) for various winding-ground and winding-winding degradation cases. The degradation cases include turn-1 to ground (T1G), turn-2 to ground (T2G), turn-3 to ground (T3G), turn-turn degradation between turn 3 and turn 4 (TT34), and turn-turn degradation between turn 5 and turn 6 (TT56). Table 3, below shows data corresponding to the graph of FIG. 7.

TABLE 3
Average value of norm of packets p10 and p11
Average value of norm of p10 and p11

| | 200 pF | 500 pF | 1000 pF |
|---|---|---|---|
| T1G | 0.8335 | 0.9695 | 1.063 |
| T2G | 0.7006 | 0.7460 | 0.7683 |
| T3G | 0.6684 | 0.6953 | 0.7102 |
| TT34 | 0.6209 | 0.6215 | 0.6220 |
| TT56 | 0.6207 | 0.6209 | 0.6212 |

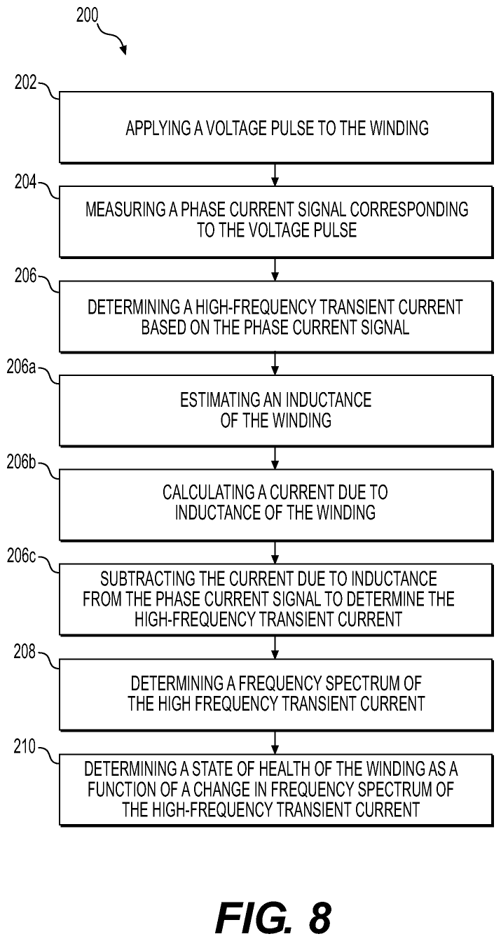

FIG. 8 is a flow chart listing steps in a first method 200 for determining and characterizing state of health of insulation of a winding in an electric machine in accordance with aspects of the present disclosure. The winding may include one or more stator windings in an electric machine 26, which may be, for example, a permanent magnet synchronous machine (PMSM). The first method 200 may be performed by the controller 30 with the inverter 20 and/or other components of the system 10. However, other devices, such as distributed processors, may perform some or all of one or more steps of the first method 200.

The first method 200 includes applying a voltage pulse to the winding at step 202 to cause a current to be supplied to the winding. The voltage pulse may take the form of a pulse-width-modulated (PWM) voltage applied to one of the motor leads 24 providing power to the electric machine 26. In some embodiments, step 202 may include the processor 32 executing instructions to cause the inverter 20 to apply the voltage pulse to the winding of the electric machine 26.

The first method 200 also includes measuring a phase current signal i(t) corresponding to the voltage pulse at step 204. The phase current signal i(t) may be measured by one or more of the current sensors 28. In some embodiments, step 204 may include the processor 32 executing instructions to measure the phase current signal i(t) based on measurements from one or more of the current sensors 28.

The first method 200 also includes determining a high-frequency transient current iₜᵣₐₙₛ based on the phase current signal i(t) at step 206. In some embodiments, step 206 may include the processor 32 executing instructions to determine the high-frequency transient current iₜᵣₐₙₛ. In some embodiments, step 206 may include: estimating an inductance of the winding at sub-step 206a; calculating a current due to inductance of the winding at sub-step 206b; and subtracting the current due to inductance from the phase current signal i(t) to determine the high-frequency transient current iₜᵣₐₙₛ at sub-step 206c. Sub-step 206b may include performing a polynomial curve fitting on the phase current signal i(t). Sub-step 206b may include other mathematical methods instead of or in addition to polynomial curve fitting.

The first method 200 also includes determining a frequency spectrum of the high-frequency transient current iₜᵣₐₙₛ at step 208. In some embodiments, step 208 may include the processor 32 executing instructions to calculate the frequency spectrum.

The first method 200 also includes determining a state of health of the winding as a function of change in frequency spectrum of the high-frequency transient current iₜᵣₐₙₛ at step 210. In some embodiments, step 210 may include the processor 32 executing instructions to calculate the state of health of the winding. In some embodiments, a mean square error is used as an indicator of the state of health of health of the winding. The mean square error of the state of health SOH_{MSE} may be calculated as:

$${SOH}_{MSE} = \frac{1}{n} {\sum }_{i = 1}^{n} {( {Y}_{i}^{ref} - {Y}_{i}^{test} )}^{2}$$

where Yᵢ^{ref} is an amplitude of a reference spectrum indicating of high-frequency transient current iₜᵣₐₙₛ of a winding with a good insulation and at a given frequency point i, Yᵢ^{test} is an amplitude of the measured high-frequency transient current iₜᵣₐₙₛ during the test at the given frequency point i.

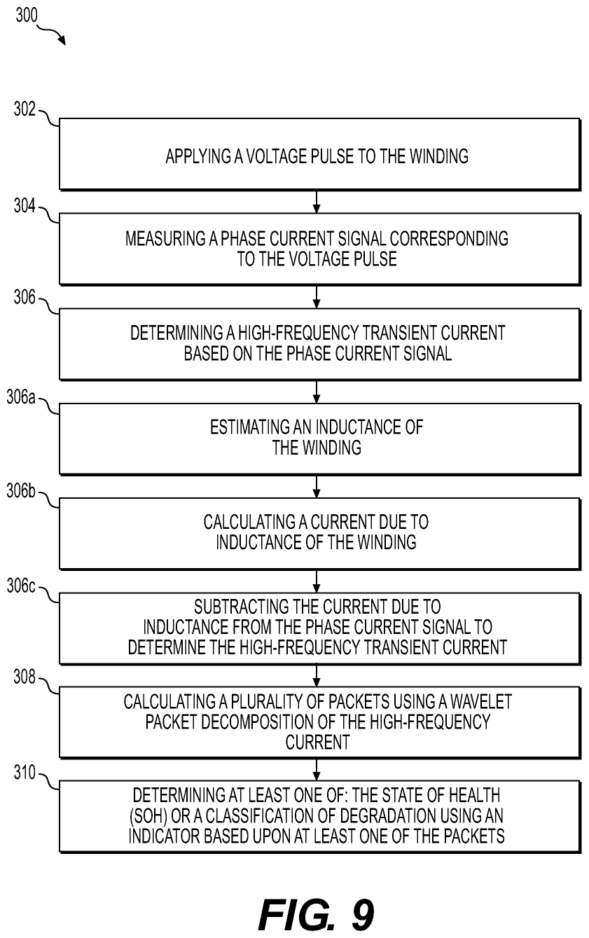

FIG. 9 is a flow chart listing steps in a second method 300 for determining and characterizing state of health of winding insulation in an electric machine in accordance with aspects of the present disclosure. The winding may include one or more stator windings in an electric machine 26, which may be, for example, a permanent magnet synchronous machine (PMSM). The second method 300 may be performed by the controller 30 with the inverter 20 and/or other components of the system 10. However, other devices, such as distributed processors, may perform some or all of one or more steps of the second method 300.

The second method 300 includes applying a voltage pulse to the winding at step 302 to cause a current to be supplied to the winding. The voltage pulse may take the form of a pulse-width-modulated (PWM) voltage applied to one of the motor leads 24 providing power to the electric machine 26. In some embodiments, step 302 may include the processor 32 executing instructions to cause the inverter 20 to apply the voltage pulse to the winding of the electric machine 26.

The second method 300 also includes measuring a phase current signal i(t) corresponding to the voltage pulse at step 304. The phase current signal may represent a current supplied to the winding due to the application of the voltage pulse. The phase current signal i(t) may be measured by one or more of the current sensors 28.

The second method 300 also includes determining a high-frequency transient current iₜᵣₐₙₛ based on the phase current signal i(t) at step 306. In some embodiments, step 306 may include the processor 32 executing instructions to determine the high-frequency transient current iₜᵣₐₙₛ. In some embodiments, step 306 may include: estimating an inductance of the winding at sub-step 306a; calculating a current due to inductance of the winding at sub-step 306b; and subtracting the current due to inductance from the phase current signal i(t) to determine the high-frequency transient current at sub-step 306c. Sub-step 306b may include performing a polynomial curve fitting on the phase current signal i(t).

The second method 300 also includes calculating a plurality of packets (ₚ₀ . . . pn) using a wavelet packet decomposition of the high-frequency current iₜᵣₐₙₛ at step 308. In some embodiments, step 308 may include the processor 32 executing instructions to calculate the plurality of packets using wavelet packet decomposition. In some embodiments, the wavelet packet decomposition includes at least a five-level decomposition producing thirty-two packets p0-p31. Alternatively, the wavelet packet decomposition may include a decomposition of greater than or less than five levels.

The second method 300 also includes determining, at step 310, at least one of: the state of health (SOH) or a classification of degradation using an indicator based upon at least one of the packets calculated at step 308. In some embodiments, step 310 may include the processor 32 executing instructions to determine the state of health (SOH) or the classification of degradation. In some embodiments, step 310 may include the processor 32 executing instructions to calculate the indicator based upon at least one of the packets. In some embodiments, the indicator is a norm of a first packet p0, which is used to determine the state of health (SOH) of the winding. In some embodiments, the indicator is average value of the norms of two subsequent packets, which are used to determine the classification of degradation is classification of degradation between a turn-turn degradation and a turn-ground degradation. For example, the two subsequent may be an 11^{th} packet (p10) and a 12^{th} packet (p11).

A method for characterizing a state of health of a winding of an electric machine is provided. The method includes: applying a voltage pulse to the winding; measuring a phase current signal corresponding to the voltage pulse; determining a high-frequency transient current based on the phase current signal; determining a frequency spectrum of the high-frequency transient current; and determining the state of health of the winding as a function of a change in the frequency spectrum of the high-frequency transient current.

In some embodiments, determining the state of health of the winding as the function of the change in the frequency spectrum includes determining a difference between the frequency spectrum of the high-frequency transient current and a reference spectrum.

In some embodiments, the reference spectrum is a spectrum associated with the electric machine in a new condition.

In some embodiments, determining the difference between the frequency spectrum of the high-frequency transient current and the reference spectrum includes calculating one of a mean square error function, a mean absolute error function, or a mean squared deviation function.

In some embodiments, the one of the mean square error function, the mean absolute error function, or the mean square deviation function includes the mean square error function; and calculating the mean square error function includes calculating the state of health (SOH_{MSE}) of the winding as:

$${SOH}_{MSE} = \frac{1}{n} {\sum }_{i = 1}^{n} {( {Y}_{i}^{ref} - {Y}_{i}^{test} )}^{2}$$

where Yᵢ^{ref} is an amplitude of the reference spectrum a given frequency point i, and Yᵢ^{test} is an amplitude of the high-frequency transient current iₜᵣₐₙₛ at the given frequency point i.

In some embodiments, determining the high-frequency transient current based on the phase current signal further includes: estimating an inductance of the winding; calculating a current due to inductance of the winding; and subtracting the current due to inductance from the phase current signal to determine the high-frequency transient current.

In some embodiments, calculating the current due to inductance of the winding includes performing a polynomial curve fitting on the phase current signal.

A method for characterizing a state of health of a winding of an electric machine is provided. The method includes: applying a voltage pulse to the winding; measuring a phase current signal corresponding to the voltage pulse; determining a high-frequency transient current based on the phase current signal; calculating a plurality of packets using a wavelet packet decomposition of the high-frequency transient current; and determining at least one of: the state of health or a classification of degradation based upon at least one packet of the plurality of packets.

In some embodiments, the wavelet packet decomposition includes at least a five-level decomposition.

In some embodiments, determining at least one of: the state of health or the classification of degradation includes determining the state of health of the winding, and wherein determining the state of health based upon the at least one packet of the plurality of packets includes determining the state of health based on a norm of a given packet of the plurality of packets.

In some embodiments, the given packet is a first packet of the plurality of packets.

In some embodiments, the at least one of the state of health or the classification of degradation includes a classification of degradation between a turn-turn degradation and a turn-ground degradation, and the indicator is an average value of the norms of two subsequent packets of the plurality of packets.

In some embodiments, the two subsequent packets of the plurality of packets are an 11^{th} packet (p10) and a 12^{th} packet (p11).

In some embodiments, determining the high-frequency transient current based on the phase current signal further comprises: estimating an inductance of the winding; calculating a current due to inductance of the winding; and subtracting the current due to inductance from the phase current signal to determine the high-frequency transient current.

In some embodiments, calculating the current due to inductance of the winding includes performing a polynomial curve fitting on the phase current signal.

The controller and its related methods and/or processes described above, and steps thereof, may be realized in hardware, software or any combination of hardware and software suitable for a particular application. The hardware may include a general purpose computer and/or dedicated computing device or specific computing device or particular aspect or component of a specific computing device. The processes may be realized in one or more microprocessors, microcontrollers, embedded microcontrollers, programmable digital signal processors or other programmable device, along with internal and/or external memory. The processes may also, or alternatively, be embodied in an application specific integrated circuit, a programmable gate array, programmable array logic, or any other device or combination of devices that may be configured to process electronic signals. It will further be appreciated that one or more of the processes may be realized as a computer executable code capable of being executed on a machine readable medium.

The computer executable code may be created using a structured programming language such as C, an object oriented programming language such as C++, or any other high-level or low-level programming language (including assembly languages, hardware description languages, and database programming languages and technologies) that may be stored, compiled or interpreted to run on one of the above devices as well as heterogeneous combinations of processor architectures, or combinations of different hardware and software, or any other machine capable of executing program instructions.

Thus, in one aspect, each method described above and combinations thereof may be embodied in computer executable code that, when executing on one or more computing devices performs the steps thereof. In another aspect, the methods may be embodied in systems that perform the steps thereof, and may be distributed across devices in a number of ways, or all of the functionality may be integrated into a dedicated, standalone device or other hardware. In another aspect, the means for performing the steps associated with the processes described above may include any of the hardware and/or software described above. All such permutations and combinations are intended to fall within the scope of the present disclosure.

The foregoing description is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A method for characterizing a state of health of a winding of an electric machine, the method comprising:
applying a voltage pulse to the winding;
measuring a phase current signal corresponding to the voltage pulse;
determining a high-frequency transient current based on the phase current signal;
determining a frequency spectrum of the high-frequency transient current; and
determining the state of health of the winding as a function of a change in the frequency spectrum of the high-frequency transient current.

2. The method of claim 1, wherein determining the state of health of the winding as the function of the change in the frequency spectrum includes determining a difference between the frequency spectrum of the high-frequency transient current and a reference spectrum.

3. The method of claim 2, wherein the reference spectrum is a spectrum associated with the electric machine in a new condition.

4. The method of claim 2, wherein determining the difference between the frequency spectrum of the high-frequency transient current and the reference spectrum includes calculating one of a mean square error function, a mean absolute error function, or a mean squared deviation function.

5. The method of claim 4, wherein the one of the mean square error function, the mean absolute error function, or the mean square deviation function includes the mean square error function; and
wherein calculating the mean square error function includes calculating the state of health (SOH_{MSE}) of the winding as
$${SOH}_{MSE} = \frac{1}{n} {\sum }_{i = 1}^{n} {( {Y}_{i}^{ref} - {Y}_{i}^{test} )}^{2}$$
where Yᵢ^{ref} is an amplitude of the reference spectrum a given frequency point i, and Yᵢ^{test} is an amplitude of the high-frequency transient current at the given frequency point i.

6. The method of claim 1, wherein determining the high-frequency transient current based on the phase current signal further comprises:
estimating an inductance of the winding;
calculating a current due to inductance of the winding; and
subtracting the current due to inductance from the phase current signal to determine the high-frequency transient current.

7. The method of claim 6, wherein calculating the current due to inductance of the winding includes performing a polynomial curve fitting on the phase current signal.

8. A method for characterizing a state of health of a winding of an electric machine, the method comprising:
applying a voltage pulse to the winding;
measuring a phase current signal corresponding to the voltage pulse;
determining a high-frequency transient current based on the phase current signal;
calculating a plurality of packets using a wavelet packet decomposition of the high-frequency transient current; and
determining, using an indicator based on the plurality of packets, at least one of: the state of health or a classification of degradation based upon at least one packet of the plurality of packets.

9. The method of claim 8, wherein the wavelet packet decomposition includes at least a five-level decomposition.

10. The method of claim 8, wherein determining the at least one of: the state of health or the classification of degradation includes determining the state of health of the winding, and wherein determining the state of health based upon the at least one packet of the plurality of packets includes determining the state of health based on a norm of a given packet of the plurality of packets.

11. The method of claim 10, wherein the given packet is a first packet of the plurality of packets.

12. The method of claim 8, wherein the at least one of the state of health or the classification of degradation includes a classification of degradation between a turn-turn degradation and a turn-ground degradation, and wherein the indicator includes an average value of norms of two subsequent packets of the plurality of packets.

13. The method of claim 12, wherein the two subsequent packets of the plurality of packets are an 11^{th} packet (p10) and a 12^{th} packet (p11).

14. The method of claim 8, wherein determining the high-frequency transient current based on the phase current signal further comprises:
estimating an inductance of the winding;
calculating a current due to inductance of the winding; and
subtracting the current due to inductance from the phase current signal to determine the high-frequency transient current.

15. The method of claim 14, wherein calculating the current due to inductance of the winding includes performing a polynomial curve fitting on the phase current signal.

16. A system for characterizing a state of health of a winding of an electric machine, the system comprising:
an inverter configured to apply an AC voltage to the electric machine and to supply current to the electric machine;
a current sensor configured to measure the current supplied to the electric machine; and
a controller in functional communication with each of the inverter and the current sensor and configured to:
command the inverter to apply a voltage pulse to the winding;
determine, based on the supply current, a phase current signal corresponding to the voltage pulse;
determine a high-frequency transient current based on the phase current signal;
determine a frequency spectrum of the high-frequency transient current; and
determine the state of health of the winding as a function of a change in the frequency spectrum of the high-frequency transient current, and
wherein determining the state of health of the winding as the function of the change in the frequency spectrum further includes determining a difference between the frequency spectrum of the high-frequency transient current and a reference spectrum.

17. The system of claim 16, wherein determining the difference between the frequency spectrum of the high-frequency transient current and the reference spectrum includes calculating one of a mean square error function, a mean absolute error function, or a mean squared deviation function.

18. The system of claim 17, wherein the one of the mean square error function, the mean absolute error function, or the mean square deviation function includes the mean square error function; and
wherein calculating the mean square error function includes calculating the state of health (SOH_{MSE}) of the winding as:
$${SOH}_{MSE} = \frac{1}{n} {\sum }_{i = 1}^{n} {( {Y}_{i}^{ref} - {Y}_{i}^{test} )}^{2}$$
where Yᵢ^{ref} is an amplitude of the reference spectrum a given frequency point i, and Yᵢ^{test} is an amplitude of the high-frequency transient current at the given frequency point i.

19. The system of claim 16, wherein determining the high-frequency transient current based on the phase current signal further comprises:
estimating an inductance of the winding;
calculating a current due to inductance of the winding; and
subtracting the current due to inductance from the phase current signal to determine the high-frequency transient current.

20. The system of claim 19, wherein calculating the current due to inductance of the winding includes performing a polynomial curve fitting on the phase current signal.
